(19) United States
(12) Patent Application Publication
(10) Pub. No.: US 2008/0100286 A1
(43) Pub. Date: May 1, 2008

(54) AUTOMATIC HEAD ALIGNMENT

(76) Inventors: Mark A. Meder, Santa Clara, CA (US); Wafaa A Abdalla, San Jose, CA (US)

Correspondence Address: Raghunath S. Minisandram;Seagate Technology LLC, Intellectual Property Department, 920 Disc Drive, SV15B1, Scotts Valley, CA, 95066, US

(21) Appl. No.: 11/555,652

(22) Filed: Nov. 1, 2006

(51) Int. Cl. G01R 33/12

(52) U.S. Cl. 324/212

(57) ABSTRACT

A spinstand includes a baseplate, a spindle mounted to the baseplate and a platform connected to the baseplate. A first component and a second component are mounted to the platform. An actuator moves the platform in a first direction relative to the baseplate, and mechanism moves the second component in approximately the first direction relative to the platform. The actuator moves the platform to position the first component at any radius of a disc placed on the spindle. The mechanism positions the second component at the same radius on an opposite surface of the disc according to a predetermined position adjustment. The first and second components are selected from a group consisting of: a burnish head, a glide head, a read head, a write head, and a read/write head. Embodiments provide automatic alignment of two components for simultaneous testing of both sides of a disc on the spinstand.

### TECHNICAL FIELD

The invention relates to testing discs that will be used in disc drives.

### BACKGROUND

In a disc drive, data is stored on a disc in concentric tracks. In many drives, the data is stored using a write head that changes a physical property of the disc. The data is read from the disc by positioning a read head over a desired track and sensing the physical properties of the disc along the track. For example, in a magnetic disc drive, the read head senses magnetic moment boundaries along the disc.

Since discs have small tracks and other features, disc manufacturing methods often involve a high degree of manufacturing complexity and are susceptible to manufacturing errors. Because of this, each production method may generate some discs that do not meet specifications. In order to detect faulty discs accurately, the discs must be tested by writing data to the disc and reading it back. In particular, each disc may be tested by writing a signal to the disc, reading the signal back, and determining if the signal was accurately written to and read from the disc. For example, this type of testing may be performed on a disc in an assembled disc drive.

Discs may also be tested on a spinstand prior to installation in a disc drive. A spinstand is a device for testing at least any one of a head and a disc. A typical spinstand comprises a granite or metal baseplate, a head positioning device fixed on the baseplate, and a disc rotating device. The head positioning device holds the head and positions the head relative to the disc. The disc rotation device holds and rotates the disc.

### SUMMARY

In general, the invention relates to automatically aligning two heads on a spinstand used for testing discs that will be used in disc drives. The spinstand includes a spindle to mount a disc for testing. The spinstand further includes a moveable platform on which the two heads are mounted. One of the heads is used for the top surface of the disc and the other is used for the bottom surface of the disc. For example, the heads may be magnetic read heads, magnetic write heads, magnetic read/write heads, or glide heads. The platform may be moved by an actuator to position the testing component at any radius of a disc mounted on the spindle. Because each of the heads is mounted to the platform, the heads are moved in unison.

Using two heads on the same platform allows both sides of a disc to be tested at once. During testing, the position of the platform is used to determine the position of the heads. The position of the bottom head relative to the platform is known from a calibration procedure in which known features on a calibration disc are found. For example, for glide heads, a bump disc is used for calibration, and for magnetic heads, a disc having known magnetic marks is used for calibration. In addition to relating the position of the bottom head to the position of the platform, the position of the top head must be related to the position of the bottom head, because manufacturing techniques are not sufficiently precise to allow each of the two heads to be located at exactly the same radius. Because both heads are moved in unison on the platform, it is preferable to have both heads at exactly the same radius of a disc to allow both heads to cover the entire surface of a disc at the same time.

Embodiments of the invention provide a mechanism that can automatically adjust the radial position of the top head relative to the bottom head such that they are radially coincident. The necessary position adjustment may be determined using a two-sided calibration disc.

In one embodiment, the invention is directed toward an assembly comprising a baseplate, a spindle mounted to the baseplate, a platform connected to the baseplate, a first component mounted to the platform, a second component mounted to the platform, an actuator that moves the platform in a first direction relative to the baseplate, and a mechanism that moves the second component in approximately the first direction relative to the platform. The actuator moves the platform to position the first component at any radius of a first surface of a disc placed on the spindle. The mechanism positions the second component at the same radius of the disc on an opposite surface of the disc according to a predetermined position adjustment. The first component and the second component are selected from a group consisting of: a burnish head, a glide head, a read head, a write head, and a read/write head.

In another embodiment, the invention is directed towards a method for testing a magnetic disc comprising placing a test disc on a spindle of a spinstand. The spinstand includes the spindle, a first component, a second component, and a mechanism that positions the second component relative to the first component. The method further includes locating the second component at the same radius of the disc as the first component with the mechanism, recording a position adjustment used by the mechanism to locate the second component at the same radius of the test disc as the first component, placing the magnetic disc on the spindle, locating the second component at the same radius of the magnetic disc as the first component with the mechanism according to the recorded position adjustment, and testing the magnetic disc using the first component and the second component. The first component and the second component are selected from a group consisting of: a glide head, a read head, a write head, and a read/write head.

The details of one or more embodiments of the invention are set forth in the accompanying drawings and the description below. Other features, objects, and advantages of the invention will be apparent from the description and drawings, and from the claims.

### BRIEF DESCRIPTION OF DRAWINGS

FIG. 1 is a schematic drawing of a spinstand.

FIG. 2 is a top view of a spinstand.

FIGS. 3A-3B are illustrations of a mechanism that positions a component on the top side of a disc at the same position as another component on the bottom side of the disc.

FIG. 4 is side view of an assembly including a first head on a bottom side of a disc and mounted on a platform and a second head on the top side of the disc and a mechanism that positions the second head at the same radius on the disc as the first head.

FIG. 5 is a flow diagram illustrating a process for calibrating a spinstand and testing a disc using the spinstand.

### DETAILED DESCRIPTION

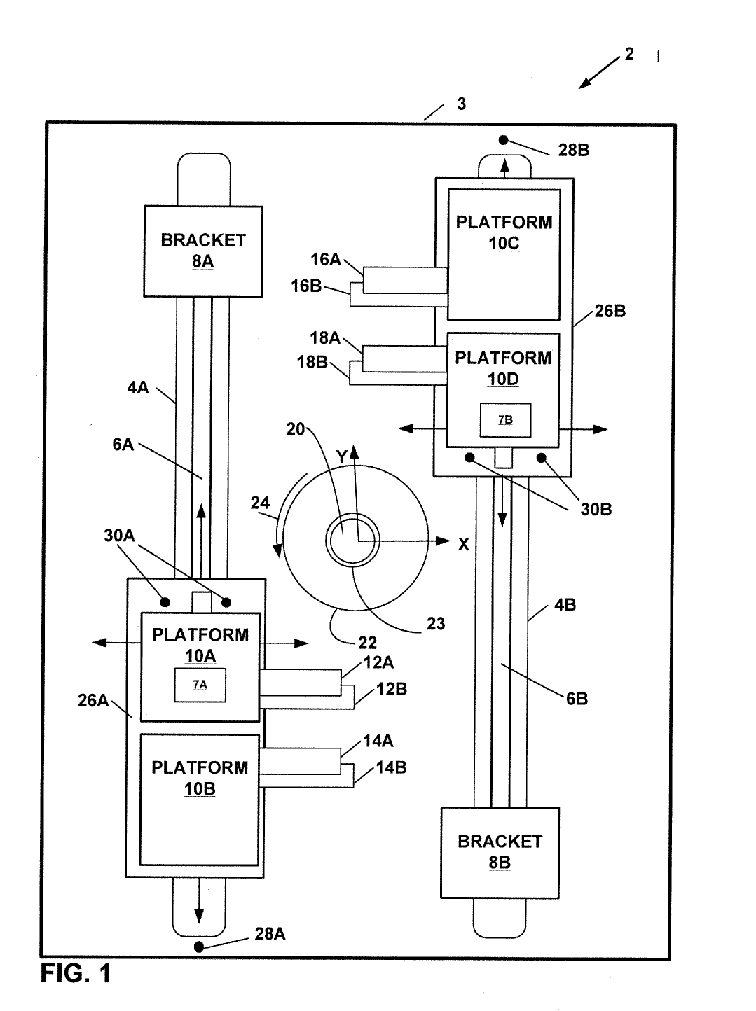

FIG. 1 is a schematic drawing of spinstand 2, which is used to test data storage discs prior to the installation of the data storage discs in a disc drive. Spinstand 2 allows a series of operations to be performed on data storage discs including, burnishing, glide testing, and spiral certification. Glide testing involves running a glide head, which includes a slider than mimics that of a read/write head in a disc drive over a surface of data storage disc to detect surface defects. Spiral certification refers to the process of writing a data pattern to the disc, reading the data pattern back, and determining if the data pattern was accurately written to and read from the disc.

Spinstand 2 includes a baseplate 3 that includes a mounting surface and provides support for components of spinstand 2. Baseplate 3 may be constructed of metal or granite to provide a heavy platform that resists vibration transmission. While granite may be used to construct baseplate 3, baseplate 3 may also be constructed from metal because it may be easier to form recesses precisely in metal than in granite. In one embodiment, baseplate 3 may be constructed of cast aluminum. A layer of nickel may be placed over the aluminum to make the surface more durable and prevent the aluminum from corroding. When baseplate 3 is constructed of aluminum, components of spinstand 2 may be electrically grounded to aluminum baseplate 3. When baseplate 3 is constructed of other materials, such as non-metal materials, a copper sheet may be mounted to baseplate 3 to facilitate grounding. In some embodiments, components of spinstand 2 are grounded to baseplate 3 using high frequency grounding, and a large surface perimeter is provided for the high frequency grounding. With high frequency grounding, high frequency noise is concentrated on the outside edges of the ground, so a surface with a large perimeter may be advantageous.

Spinstand 2 includes a spindle 20 mounted at approximately the center of baseplate 3 and sized to receive disc 22. Disc 22 may be, for example, a magnetic data storage disc. Spindle 20 rotates in order to rotate disc 22 in the direction indicated by arrow 24. Disc 22 has a top surface and a bottom surface, both of which are approximately parallel with baseplate 3 when disc 22 is placed on spindle 20. When disc 22 is placed on spindle 20, the bottom surface is closer to baseplate 3, and the top surface is farther away from baseplate 3.

Baseplate 3 includes recesses 4A and 4B (collectively, “recesses 4”) to accommodate actuators 6A and 6B, respectively. Actuators 6A and 6B (collectively, “actuators 6”) may be mounted in recesses 4A and 4B by brackets 8A and 8B, respectively. Recesses 4 may be formed by using any technique known in the art, e.g., machining or cast molding.

Carriages 26A and 26B (collectively, “carriages 26”) may be affixed to actuators 6A and 6B and be located above recesses 4A and 4B, respectively. Carriage 26A holds platforms 10A and 10B and carriage 26B holds platforms 10C and 10D. Collectively, platforms 10A, 10B, 10C, and 10D may be referred to herein as “platforms 10”. Each of platforms 10 includes a top head and a bottom head. As illustrated in the example of FIG. 1, platform 10A includes top head 12A and bottom head 12B, platform 10B includes top head 14A and bottom head 14B, platform 10C includes top head 16A and bottom head 16B, and platform 10D includes top head 18A and bottom head 18B.

Actuators 6 may move carriages 26 in the y-direction. Because platforms 10A and 10B are attached to carriage 26A, platforms 10A and 10B and their respective heads move along with carriage 26A in the y-direction. Likewise, because platforms 10C and 10D are attached to carriage 26B, platforms 10C and 10D and their respective heads move along with carriage 26B in the y-direction. The movement of the carriage 26A along the y-direction is further limited at the extreme end by a mechanical hard stop 28A, to limit the movement of the platform. The movement of the carriage 26B along the y-direction is further limited at the extreme end by a mechanical hard stop 28B, to limit the movement of the platform. In the alternative, an electrical or optical limit switch positioned near the extreme end may be used to limit the range of movement of carriage and thus limiting the movement of the platforms. Thus, by moving carriages 26 in the y-direction, actuators 6 may position any of the heads at any radius of disc 22.

In addition, platform 10A and platform 10D include actuators 7A and 7B (collectively, actuators 7), respectively. Actuators 7 enable platforms 10A and 10D to move independently along the x-axis. Movement along the x-axis may be necessary to prevent heads 12A and 12B and heads 18A and 18B from colliding with spindle 20 when actuators 6 position heads 14A and 14B or heads 16A and 16B at a minimum usable inner diameter 23 of disc 22. The movement of platform 10A along the x-axis is further limited at the extreme ends by a pair of mechanical hard stops 30A, within a predetermined range. The movement of platform 10D along the x-axis is further limited at the extreme ends by a pair of mechanical hard stops 30B.

Furthermore, each of platforms 10 include actuators to raise and lower respective top heads onto disc 22. In addition, platforms 10 include actuators to raise and lower respective bottom heads onto disc 22. When the actuators lower top heads onto disc 22 and raise the bottom heads up to disc 22, the top heads and bottom heads may access disc 22. When a top head is not in use, the actuator raises the top head away from disc 22. Similarly, when a bottom head is not in use, the actuator lowers the bottom head away from disc 22.

Top head 12A and bottom head 12B may be used to burnish disc 22 and may be collectively referred to herein as “burnish heads 12.” The process of burnishing disc 22 removes protrusions from the data surfaces of the data storage disc to reduce surface roughness. To burnish disc 22, actuator 6B moves carriage 26B away from disc 22 and actuator 6A moves carriage 26A toward disc 22. When actuator 6A has moved burnish heads 12A and 12B over and under disc 22 respectively, actuators on platform 10A lower top head 12A and raise bottom head 12B such top head 12A and bottom head 12B access disc 22. When spindle 20 rotates disc 22, burnish heads 12 brush the surfaces of disc 22 to remove protrusions from the surfaces.

Top head 18A and bottom head 18B may be used to perform a glide test on disc 22 and may be referred to herein as “glide heads 18.” To perform a glide test, actuator 6A moves carriage 26A away from disc 22 and actuator 6B moves carriage 26B toward disc 22. When actuator 6B has moved glide heads 18A and 18B over and under disc 22 respectively, actuators on platform 10D lower top head 18A and raise bottom head 18B such that top head 18A and bottom head 18B access with disc 22. When spindle 20 rotates disc 22, glide heads 18 may collide with protrusions on the surfaces of disc 22 that remain after a burnishing process. Glide heads 18 may include piezoelectric crystals to produce small electrical voltages when glide heads 18 collide with the protrusions. Circuitry on platform 10D may amplify these electrical voltages and transmit them to a control system (not shown). The control system may then abort the glide test and initiate a new burnishing process on disc 22.

Top head 14A and bottom head 14B may write data to disc 22 and may be collectively referred to herein as “write heads 14.” Furthermore, top head 16A and bottom head 16B may read data from disc 22 and may be referred to herein as “read heads 16.” Write heads 14 and read heads 16 may be used to perform a spiral certification test on disc 22. To perform a spiral certification test, actuator 7A moves platform 10A away from disc 22 along the x-axis and actuator 7B moves platform 10D away from disc 22 along the x-axis. Actuator 6A may then position carriage 26A such that write heads 14A and 14B are over and under disc 22 respectively. Actuators on platform 10B may then lower head 14A and raise head 14B such that heads 14A and 14B access disc 22. Actuator 6B then positions carriage 26B such that read heads 16 may read a data pattern written by write heads 14 one-half revolution of disc 22 after write heads 14 write the data pattern to disc 22. That is, actuator 6B positions read heads 16 such that read heads 16 are one-half track pitch away from spindle 20 as compared to write heads 14. Track pitch is a measure of how far write heads 14 move along the y-axis per revolution of spindle 20. After actuator 6B so positions carriage 26B, actuators on platform 10C may lower head 16A and raise head 16B such that head 16A and head 16B access disc 22.

While spindle 20 rotates disc 22, write heads 14 write a data pattern to disc 22 and read heads 16 attempt to read the data pattern from disc 22 just written by write heads 14. At the same time, actuator 6A may move carriage 26A toward inner diameter 23 of disc 22. As actuator 6A moves carriage 26A, actuator 6B moves carriage 26B toward inner diameter 23 of disc 22 at the same speed. In this way, write heads 14 write a spiral of data on disc 22 and read heads 16 attempt to read this spiral of data. Circuitry on platform 10C amplifies signals read by read heads 16 send the signals to the control system. The control system may then determine whether read heads 16 read from disc 22 what write heads 14 wrote to disc 22. For instance, the control system may determine that data written to disc 22 was not read by read heads 16. This may indicate that the surface of disc 22 may not be properly holding magnetic charges. If read heads 16 did not read the data that write heads 14 wrote to disc 22, the control system may initiate a new spiral certification test. If, during the new spiral certification test, read heads 16 do not read the data the write heads 14 wrote to disc 22 at the same position, the control system may alert a user that disc 22 contains a defect.

Platforms 10B, 10C, and 10D may also include alignment actuators (not shown) to align their respective top heads with their respective bottom heads. In other words, alignment actuators on platforms 10B, 10C, and 10D move top heads 14A, 16A, and 18A such that top heads 14A, 16A, and 18A are precisely aligned with bottom heads 14B, 16B, and 18B. For example, to align write heads 14, actuator 6A positions carriage 26A such that bottom head 14B detects a track previously written on disc 22. While maintaining the position of carriage 26A, disc 22 may then be flipped over such that the same track is now facing top head 14A. The alignment actuator may then adjust the position of top head 14A until top head 14A detects the track. After write heads 14 are aligned, a new disc may be loaded onto spindle 20 and write heads 14 may write a track to both surfaces of the new disc. Actuator 6B may then move carriage 26B such that bottom read head 16B detects the track. An alignment actuator on platform 10C may then position top read head 16A such that top read head 16A detects the track. At this point read heads 16 are aligned. To align glide heads 18, a disc with a bump at a known radius is placed on spindle 20. Actuator 6B then moves carriage 26B such that bottom glide head 18B collides with the bump. While maintaining the position of carriage 26B, the disc with the bump may then be flipped over and an alignment actuator may position top glide head 18A such that top glide head 18A also collides with the bump. When top glide head 18A collides with the bump, glide heads 18 are aligned. Such an alignment actuator may not be necessary on platform 10A because heads 12A and 12B may used to burnish disc 22 and precise alignment of heads 12A and 12B may not be necessary to burnish disc 22. Rather, burnish heads 12 may be aligned visually.

In other embodiments, two discs may be “sandwiched” together on spindle 20 and one side of both discs may be tested simultaneously. This technique may be particularly suited for single-sided discs.

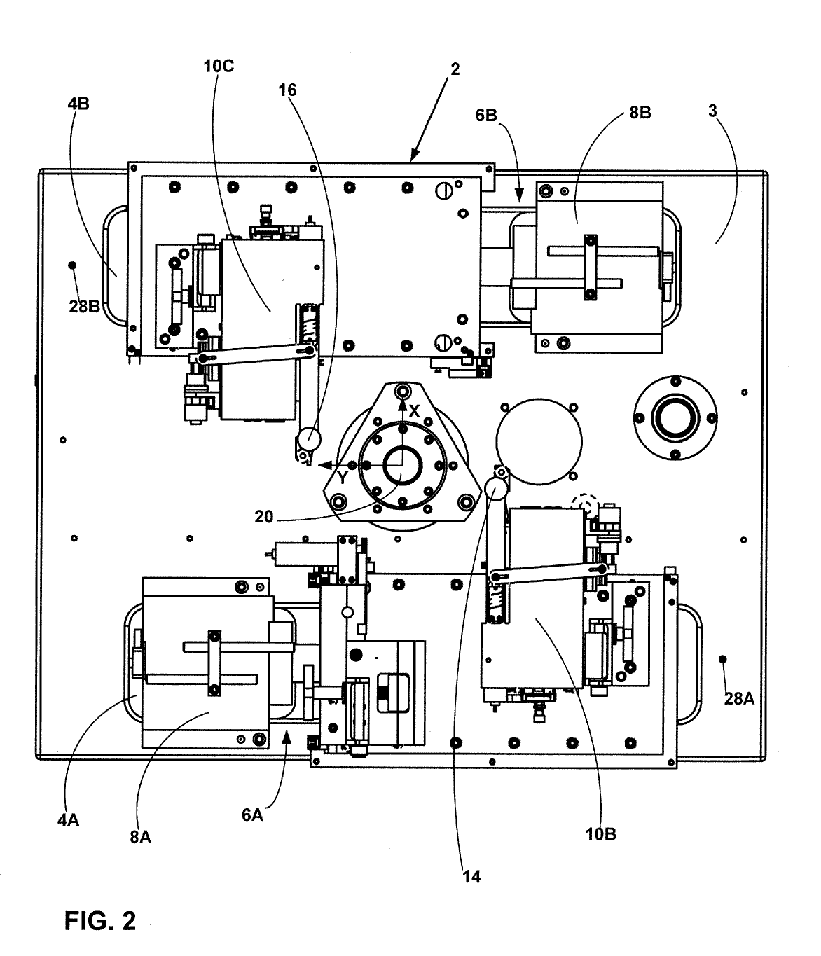

FIG. 2 is a top view illustrating an exemplary embodiment of spinstand 2 that may be used for disc testing. As described with respect to FIG. 1, actuators 6 are mounted inside recesses 4 using brackets 8. Write heads 14 and read heads 16 are moved by actuators 6, 7B, and 7C in order to access disc 22 (not shown in FIG. 2) placed on spindle 20. As shown in FIG. 2, platforms 10B and 10C include a mechanism that positions the second component at the same radius of the disc as the first component according to a predetermined position adjustment.

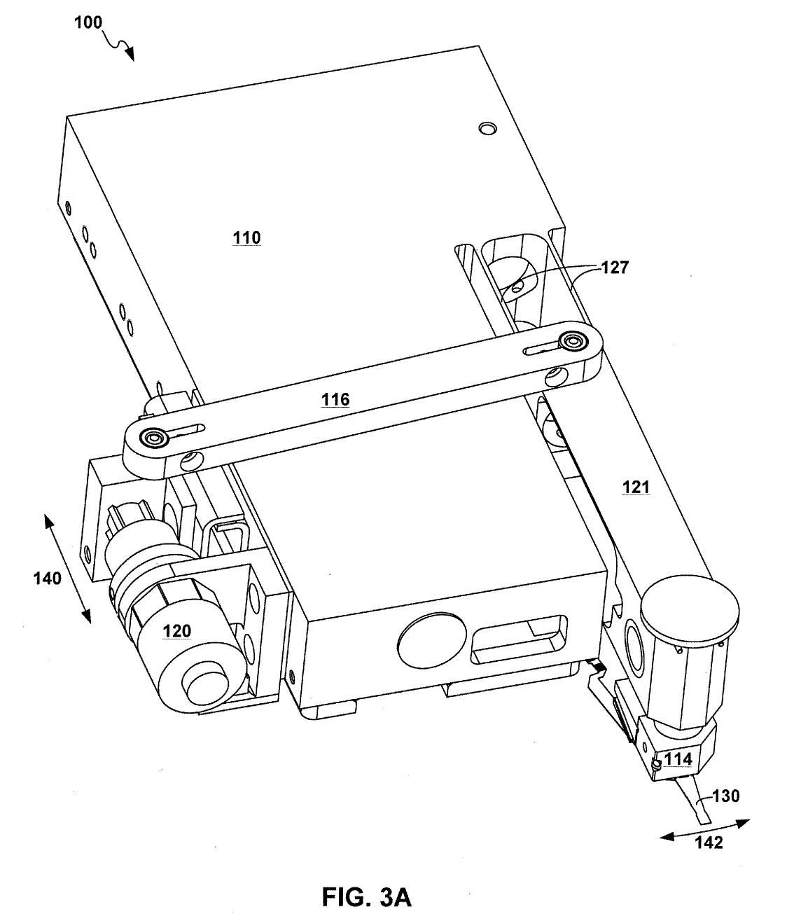

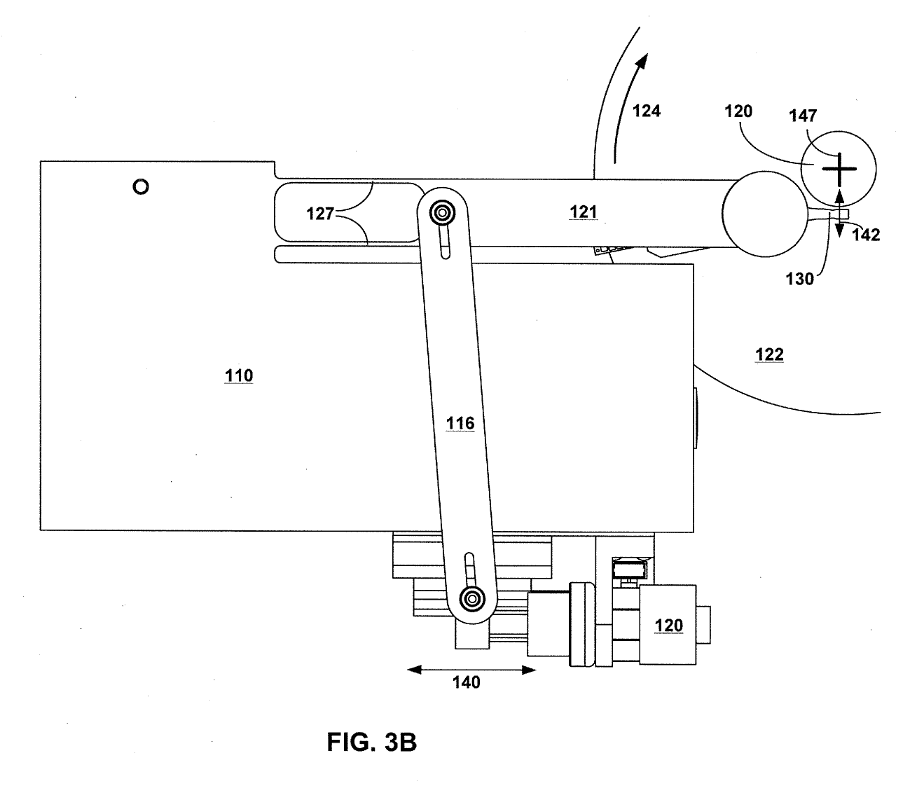

FIGS. 3A-3B are illustrations of mechanism 100 that positions head 130 on the top side of disc 122 at the same position as another head on the bottom side of disc 122. Disc 122 is mounted on spindle 120, which rotates disc 122 in direction 124. Disc 122 may be, for example, a magnetic disc for a disc drive. Head 130 may be, for example, a glide head, a read head, a write head, or a read/write head. Mechanism 100 is mounted to base 110, which is attached to a platform of a spinstand, e.g., one of platforms 10 on spinstand 2 (FIGS. 1-2). Mechanism 100 includes arm 121, which is attached to the platform via base 110. Arm 121 includes flexures 127. Head 130 is mounted to arm 121 opposite to flexures 127 relative to the platform on head support platform 1 14. Mechanism 100 includes actuator 120, which may include, for example, a stepper motor which precisely controls the position of actuator 120. Mechanism 100 also includes linkage 116. Linkage 116 moveably connects actuator 120 to arm 121.

Mechanism 100 is operable to move head 130 in direction 142 by moving actuator 120 in direction 140. Direction 142 is approximately perpendicular to direction 140. This allows a larger motion in direction 140 to be transferred to a much smaller motion of head 130 in direction 142. Direction 142 is approximately in line with axis of rotation 147 of spindle 120 and disc 122 such that mechanism 100 substantially actuates head 130 radially and not circumferentially relative to disc 122. Mechanism 100 is used to position head 130 at the same radial position as another head on the opposite side of disc 122 (not shown in FIGS. 3A-3B).

Mechanism 100 may actuate head 130 according to a predetermined position adjustment determined using a calibration disc to locate head 130 at the same radial position as another head on the opposite side of disc 122. For example, the predetermined position adjustment may be less than one-tenth of an inch, less than fifty-thousands of an inch, less than ten-thousands of an inch and may even be less than three-thousands of an inch.

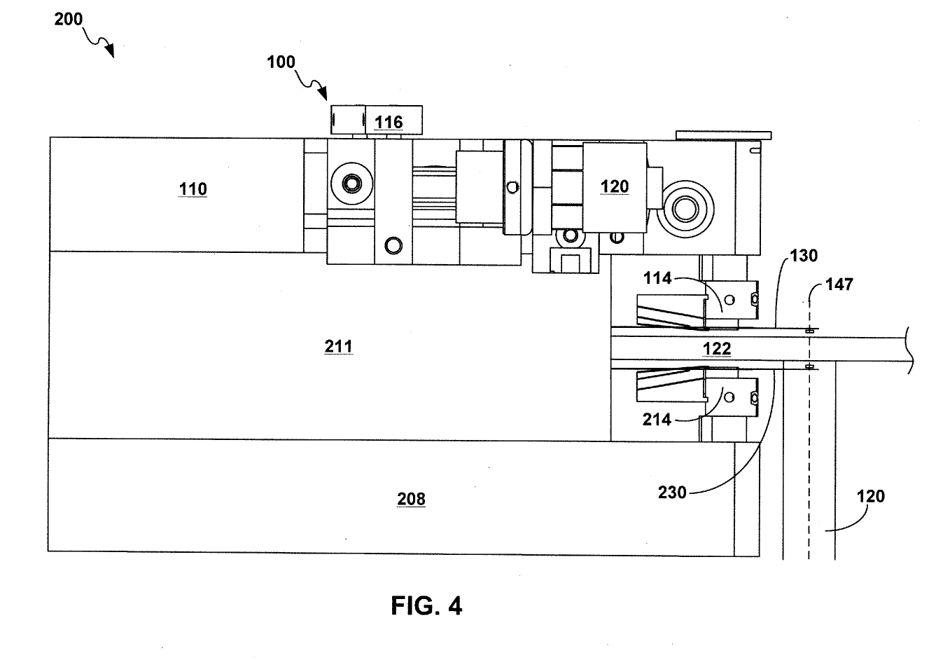

FIG. 4 is side view of assembly 200. Assembly 200 includes mechanism 100 (FIGS. 3A-3B). Assembly 200 includes head 230 in addition to head 130. Heads 130 and 230 are shown in an unloaded position relative to disc 122, but are loaded on disc 122 during testing. Head 230 is fixably coupled to platform 208 on head support platform 214, while head 130 is coupled to platform 208 via mechanism 100, base 110 and spacer 211. Platform 208 may be, for example, the same as one of platforms 10 (FIGS. 1-2).

Heads 130 and 230 may be glide heads, read heads, write heads, or read/write heads. Generally, both of heads 130 and 230 will be the same type of head, but in some embodiments heads 130 and 230 may be different types of heads. However, using the same type of head may simplify testing of disc 122 as the same operations can be performed simultaneous on both sides of disc 122. For example, if heads 130 and 230 are both write heads, heads 130 and 230 may write coincident signals on disc 122 simultaneously.

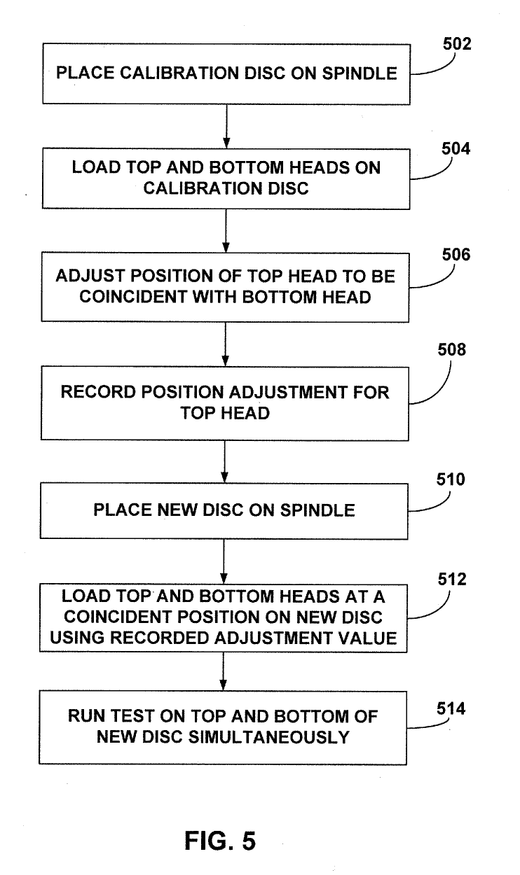

FIG. 5 is a flow diagram illustrating a process for calibrating a spinstand and testing a disc using the spinstand. For clarity, the process shown in FIG. 5 is described with respect to assembly 200 (FIG. 4). First a calibration disc is mounted on spindle 120 (502). Then heads 130 and 230 are loaded on the test disc (504). For example, if heads 130 and 230 are glide heads, the test disc may be a bump disc. If heads 130 and 230 are read heads, the test disc may include magnetic signals.

Once heads 130 and 230 are loaded on the test disc, mechanism 100 is used to located head 130 at the same radial position on the test disc as head 230 (506). The position adjustment required to locate head 130 at the same radial position on the test disc as head 230 is recorded (508). For example, if actuator 120 includes a stepper motor, the count of the stepper motor may be recorded.

Then the test disc is removed and disc 122 mounted on spindle 120 (510). Heads 130 and 230 are loaded on disc 122 at the same radial position by setting mechanism 100 according to the recorded position adjacent (512). For example, the recorded position adjustment may be less than one-tenth of an inch, less than fifty-thousands of an inch, less than ten-thousands of an inch and may even be less than three-thousands of an inch. Once heads 130 and 230 are loaded on disc 122, heads 130 and 230 are used to perform a testing operation simultaneously on both sides of disc 122 (514). For example, the testing operation may include glide testing or spiral certification. Once testing of disc 122 is completed, one or more additional discs may be tested using the same recorded position adjustment.

Various embodiments of the invention have been described. However, various modifications to the described embodiments can be made within the spirit of the invention. For example, a mechanism can be used to position a component other than a head, such as a burnish head, at the same radius as another component on a disc mounted on a spinstand. These and other embodiments are within the scope of the following claims.

1. An assembly comprising:
a baseplate;
a spindle mounted to the baseplate;
a platform connected to the baseplate and movable within a predetermined range;
a first component mounted to the platform;
a second component mounted to the platform;
an actuator that moves the platform in a first direction relative to the baseplate; and
a mechanism that moves the second component in approximately the first direction relative to the platform,
wherein the actuator moves the platform to position the first component at any radius of a first surface of a disc placed on the spindle,
wherein the mechanism positions the second component at the same radius of the disc on an opposite surface of the disc according to a predetermined position adjustment, and
wherein the first component and the second component are selected from a group consisting of: a burnish head, a glide head, a read head, a write head, and a read/write head.

2. The assembly of claim 1, wherein the first component is a first write head and the second component is a second write head.

3. The assembly of claim 2, wherein the platform is a first platform, wherein the mechanism is a first mechanism, wherein the actuator is a first actuator, wherein the predetermined position adjustment is a first predetermined position adjustment, further comprising:
a second platform connected to the baseplate;
a first read head attached to the second platform;
a second read head attached to the second platform;
a second actuator that moves the second platform in a second direction relative to the baseplate; and
a second mechanism that moves the second read head in the second direction relative to the platform,
wherein the first write head writes a first signal to the first surface of the disc,
wherein the second write head writes a second signal to the opposite surface of the disc,
wherein the second actuator moves the second platform to position the first read to read the first signal,
wherein the second mechanism positions the second read head to read the second signal according to a second predetermined position adjustment.

4. The assembly of claim 3, wherein the second direction is parallel to the first direction.

5. The assembly of claim 3, wherein the first signal is coincident with the second signal on the disc.

6. The assembly of claim 1, wherein the actuator is a first actuator, wherein the mechanism includes:
an arm attached to the platform, wherein the arm includes a flexure, wherein the second component is mounted to a portion of the arm that is opposite the flexure relative to the platform;
a second actuator mounted to the platform;
a linkage that moveably connects the second actuator to the portion of the arm that is opposite the flexure relative to the platform.

7. The assembly of claim 6, wherein the second actuator moves in a second direction that is approximately perpendicular to the first direction.

8. The assembly of claim 1, wherein the predetermined position adjustment is less than one-tenth of an inch.

9. The assembly of claim 1, wherein the predetermined position adjustment is less than fifty-thousands of an inch.

10. The assembly of claim 1, wherein the predetermined position adjustment is less than ten-thousands of an inch.

11. The assembly of claim 1, wherein the predetermined position adjustment is less than three-thousands of an inch.

12. The assembly of claim 1, wherein the actuator is a first actuator, wherein the first actuator moves the platform in a first direction, further comprising a second actuator, wherein the second actuator positions the platform such that the first component and the second component are located along a centerline of the disc that is approximately parallel to the first direction.

13. The assembly of claim 1, wherein the actuator is a first actuator, wherein the first actuator moves the platform in a first direction, further comprising a second actuator, wherein the second actuator positions the platform to move the component attached to the platform along a centerline of the disc that is approximately parallel to the first direction.

14. The assembly of claim 1, further comprising the disc, wherein the disc is mounted on the spindle.

15. The assembly of claim 1, wherein the disc is a recordable magnetic disc.

16. A method for testing a magnetic disc comprising:
placing a test disc on a spindle of a spinstand, wherein the spinstand includes:
the spindle,
a platform movable within a predetermined range,
a first component located on said platform,
a second component on said platform, and
a mechanism that positions the second component relative to the first component,
locating the second component at the same radius of the disc as the first component with the mechanism;
recording a position adjustment used by the mechanism to locate the second component at the same radius of the test disc as the first component;
placing the magnetic disc on the spindle;
locating the second component at the same radius of the magnetic disc as the first component with the mechanism according to the recorded position adjustment; and
testing the magnetic disc using the first component and the second component,
wherein the first component and the second component are selected from a group consisting of: a glide head, a read head, a write head, and a read/write head.

17. The method of claim 16, wherein the test disc is a bump disc, wherein the first component is a first glide head and the second component is a second glide head, testing the magnetic disc using the first component and the second component includes glide testing the magnetic disc.

18. The method of claim 16, wherein the mechanism includes an arm including a flexure, an actuator, and a linkage that moveably connects the actuator to the arm, wherein the second component is mounted to the arm, wherein the actuator bends the flexure to locate the second component at the same radius of the magnetic disc as the first component.

19. The method of claim 16, wherein the position adjustment is less than one-tenth of an inch.

20. The method of claim 16, wherein the position adjustment is less than fifty-thousands of an inch.
